(19) United States
(12) Patent Application Publication
(10) Pub. No.: US 2023/0261067 A1
(43) Pub. Date: Aug. 17, 2023

(54) SILICON NANOSHEET AND 2D PARALLEL CHANNEL VERTICAL FET DESIGN WITH WAFER TRANSFER TECHNOLOGY AND METAL FIRST APPROACH

(71) Applicant: Tokyo Electron Limited, Tokyo (JP)

(72) Inventors: H. Jim Fulford, Albany, NY (US); Mark I. Gardner, Albany, NY (US); Partha Mukhopadhyay, Albany, NY (US)

(73) Assignee: Tokyo Electron Limited, Tokyo (JP)

(21) Appl. No.: 17/672,488

(22) Filed: Feb. 15, 2022

(51) Int. Cl. H01L 29/417; H01L 29/423; H01L 29/786; H01L 29/78

(52) U.S. Cl. CPC H01L 29/41783; H01L 29/42392; H01L 29/78696; H01L 29/7856

(57) ABSTRACT

One or more 3D VFET structures with 2D material based channels using a wafer transfer technology and a metal first approach are disclosed. Transistor devices can be formed, where each transistor can include an elongate structure extending vertically from a first/source drain contact, a first end of the elongate structure in electrical contact with the first source/drain contact and a second end of the elongate structure in electrical contact with a second source/drain contact. The transistor can also include a channel that includes a 2D material layer extending along an external surface of the elongate structure and a gate structure including a high-k dielectric extending along the 2D material and a gate metal in contact with the high-k dielectric. The 2D material can laterally surround the elongate structure and the gate structure can surround the 2D material.

### TECHNICAL FIELD

The present invention relates generally to the field of manufacturing semiconductor devices.

### BACKGROUND

Modern semiconductor integrated circuit device fabrication normally relies on well-established processes, such as film-forming depositions, etch mask creation, patterning, material etching and removal, and doping treatments, many of which are performed repeatedly to form desired circuits on a substrate. At the same time, the semiconductor industry has been facing a challenge in scaling down and continuing to improve the performance of integrated circuits to reduce their power consumption while increasing their rate of operation. In conventional integrated circuit fabrication, structures are usually manufactured in one active device plane, while wiring or metallization layers are typically formed above the active device plane. Although scaling efforts of the integrated circuits has improved over the years, resulting in a larger number of transistors per unit area, continued improvement has been a challenge as individual transistor feature sizes become smaller. Integrated device fabricators have expressed a desire for new solutions to enable further device performance improvement along with the scaling.

### SUMMARY

Faced with the challenge of fabricating transistors having feature sizes on the order of several atom sizes, fabricators of integrated circuits (“IC”) find it increasingly difficult to further scale down transistor features without compromising various device aspects. An area of growing interest has been usage of nanosheets that utilize very thin material structures on which 2D material having only a single molecular layer can be applied. Fabricating ICs, including transistors, logic gates, memory or similar using these structures can be challenging. The issue is even further exacerbated if the desired process utilizes conventional manufacturing steps to further scale down transistor sizes thereby increasing circuit density. The solution provided herein addresses these and other similar challenges by providing nanosheet-based design for fabricating parallel channel vertical field effect transistor (“VFET”) using the wafer transfer technology and the metal first approach.

The present solution can provide an improved circuit density using techniques that utilize conventional manufacturing steps and therefore allow for this improvement to be achieved at a reduced manufacturing cost. The present disclosure relies on oxide-to-oxide bond and utilizes an intrinsic silicon wafer and implant later approach to form a junction transistor. The present disclosure also relies on a metal first layer design to fabricate the transistors using silicon nanosheets.

In some aspects the present disclosure relates to a device that includes a transistor device or a combination of transistor devices. The device can include an elongate structure extending vertically from a first/source drain contact, a first end of the elongate structure in electrical contact with the first source/drain contact. The device can include a second end of the elongate structure in electrical contact with a second source/drain contact. The device can include a channel that includes a 2D material layer extending along an external surface of the elongate structure. The device can include a gate structure including a high-k dielectric extending along the 2D material and a gate metal in contact with the high-k dielectric.

The device can include the 2D material layer in contact with and forming a ring around the external surface of the elongate structure. The device can include the high-k dielectric in contact with and forming a ring around the 2D material layer and the gate metal forming a ring around the high-k dielectric. In some implementations, the first source/drain contact of the device is formed in a material of a first substrate and the elongate structure is formed in a material of a second substrate.

In some implementations, the device can include a silicide layer disposed between the elongate structure and the first source/drain contact. The device can also include a layer of dielectric material disposed between the gate structure and the first source/drain contact. The device can further include the elongate structure comprising a doped semiconductor material.

The device can include a second doped semiconductor material of the elongate structure comprising a first polarity and the doped semiconductor material comprising a second polarity, the doped semiconductor material and the second doped semiconductor material forming a p-n junction. The device can include a second elongate structure extending vertically from a third source/drain contact and a first end of the second elongate structure in electrical contact with the third source/drain contact. The device can also include a second end of the second elongate structure in electrical contact with a second source/drain contact.

The device can also include a second channel including a 2D material layer extending along an external surface of the elongate structure. The device can also include a second gate structure including a high-k dielectric extending along the 2D material and a gate metal in contact with the high-k dielectric, wherein the second elongate structure is formed above the elongate structure.

The device can include the third source/drain contact formed above the first source/drain contact and the second source/drain contact. The device can include a majority of the elongate structure comprising a semiconductor material doped with a first polarity and a cross-sectional slice of semiconductor material doped with a second polarity. The device can also include a majority of the second support structure comprising a semiconductor material doped with the second polarity and a cross-sectional slice of semiconductor material doped with the first polarity.

In some aspects the present disclosure relates to a method. The method can be a method for fabricating a transistor or a combination of transistors. The method can include forming an elongate structure extending vertically from a first/source drain contact, a first end of the elongate structure in electrical contact with the first source/drain contact. The method can also include forming a second end of the elongate structure in electrical contact with a second source/drain contact. The method can include forming a channel including a 2D material layer extending along an external surface of the elongate structure. The method can further include forming a gate structure including a high-k dielectric extending along the 2D material and a gate metal in contact with the high-k dielectric.

The method can include forming a ring of the 2D material layer in contact with and around the external surface of the elongate structure. The method can include forming a ring of high-k dielectric in contact with and around the 2D material layer. The method can include forming a ring of the gate metal in contact with and around the high-k dielectric.

The method can include forming first source/drain contact in a material of a first substrate, and forming the elongate structure in a material of a second substrate. The method can include forming a silicide layer between the elongate structure and the first source/drain contact. The method can include forming a layer of dielectric material between the gate structure and the first source/drain contact.

The method can include forming the elongate structure including a doped semiconductor material. The method can also include forming a second doped semiconductor material of the elongate structure comprising a first polarity and forming the doped semiconductor material comprising a second polarity, the doped semiconductor material and the second doped semiconductor material forming a p-n junction. The method can include forming a second elongate structure extending vertically from a third source/drain contact a first end of the second elongate structure in electrical contact with the third source/drain contact and forming a second end of the second elongate structure in electrical contact with a second source/drain contact. The method can include forming a second channel a 2D material layer extending along an external surface of the elongate structure. The method can also include forming a second gate structure including a high-k dielectric extending along the 2D material and a gate metal in contact with the high-k dielectric, wherein the second elongate structure is formed above the elongate structure.

The method can include comprising the third source/drain contact formed above the first source/drain contact and the second source/drain contact. The method can also include forming a portion of the elongate structure comprising a semiconductor material doped with a first polarity and a cross-sectional slice of semiconductor material doped with a second polarity. The portion of the elongate structure can comprise a majority of the elongate structure. The method can further include forming a portion of the second support structure comprising a semiconductor material doped with the second polarity and a cross-sectional slice of semiconductor material doped with the first polarity. The portion of the second support structure can comprise a majority of the second support structure.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. Aspects can be combined and it will be readily appreciated that features described in the context of one aspect of the present disclosure can be combined with other aspects. Aspects can be implemented in any convenient form. As used in the specification and in the claims, the singular form of ‘a’, ‘an’, and ‘the’ include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIGS. 1-16 include cross-sectional and top-down of a fabrication flow for manufacturing a single layer of 3D VFET structures with a 2D material based channel using a wafer transfer technology and a metal first approach, according to an embodiment.

FIGS. 17-26 include cross-sectional, top-down views of a fabrication flow for manufacturing N-number of stacks of 3D VFET structures with 2D material based channels using a wafer transfer technology and a metal first approach, according to an embodiment.

FIG. 27 is a flow diagrams of example methods for fabricating 3D CFET structures using process flows described in connection with FIGS. 1-26, according to an embodiment.

### DETAILED DESCRIPTION

References will now be made to various illustrative embodiments depicted in the drawings, and specific language will be used to describe the same. It will nevertheless be understood that no limitation of the scope of the claims or this disclosure is thereby intended. Alterations and further modifications of the inventive features illustrated herein, and additional applications of the principles of the subject matter illustrated herein, which would be apparent to one of ordinary skill in the relevant art having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

It is understood that apparatuses, systems and devices produced by the structures described herein can be used or find their application in any number of electronic devices utilizing structures and/or circuits described herein, such as for example, controllers, memory chips, systems or process on a chip processors, graphics processing units, central processing units and more. For example, structures and/or circuits described herein can include a part of systems utilizing memory, such as any computing systems including for example: computers, phones, servers, cloud computing devices, and any other device or system that utilizes integrated circuit devices.

The embodiments described herein may enable an increased stack height of one or more 3D semiconductor devices. Therefore, a semiconductor substrate can be used, but is not required, and any base layer material (e.g., glass, organic, etc.) may be used instead of a traditional silicon substrate. A base layer, therefore, can be a semiconductor substrate, such as a silicon substrate. Some embodiments include 3D stacks of vertical conductive channel nanosheets in both CFET and side-by-side configurations.

The process flows described herein utilize conductive dielectric materials to form NMOS and PMOS devices. As such, the techniques described herein can be used to produce devices that are manufactured, or “stacked” on any existing vertically stacked device or substrate, according to various implementations. The present techniques may improve upon other semiconductor manufacturing techniques by increasing the N height of stacked semiconductor devices, such as transistors, thereby providing high density logic. Although illustrations herein may show an NMOS device arranged over a PMOS device, alternative configurations may include a PMOS device over NMOS device, NMOS device over NMOS device, PMOS device over PMOS device, or other alternative including one or more NMOS devices or PMOS devices for any number of N stacks and in any order or arrangement.

Dielectric materials used herein can be any material or materials having low electrical conductivity, such as for example one millionth of a mho/cm. Dielectric materials can include, for example, silicon dioxide, silicon nitride, nanoporous silica, hydrogensilsesquioxanes (HSQ), Teflon-AF (polytetrafuoethene or PTFE), silicon oxyflouride. Dielectric materials can also include, for example, ceramics, glass, mica, organic and oxides of various metals.

High-k dielectric, also referred to as high k material, can refer to any material with a higher dielectric constant as compared to the silicon dioxide. For example, high-k dielectric can include hafnium silicate, zirconium silicate, hafnium dioxide, zirconium dioxide, and others.

Various metals, such as gate metal and the source/drain metal, can be used herein and can include any metal or any electrically conductive material. For example metals used in the present solution can include aluminum, copper, titanium, tungsten, silver, gold or any other metal. For the purposes of the present solution, in addition to the metals, source/drain metals or gate metals can also include other electrically conductive materials, such as highly doped semiconductors, for example.

The present solution can also utilize 2D materials for forming transistor channels. 2D materials can include, for example, but are not limited to, WS2, WSe2, WTe2, MoS2, MoSe2, MoTe2, HfS2, ZrS2, and TiS2, GaSe, InSe, phosphorene, and other similar materials. These materials can be deposited by an atomic layer deposition (ALD) process and may be about 5-15 angstroms thick, the thinness lending to their name—2D material. 2D material layer can, depending on the material and design, and can have a broader range of thicknesses, such as between 0.2 nm and 3 nm, for example. 2D materials may be annealed during or after the device formation process to recrystallize or grow the crystals and thereby improve electrical characteristics. 2D materials, for example, can be electrically conductive.

Additionally or alternatively, 2D materials to be used for forming 2D channels may comprise one or more semiconductive-behaving materials, which may be formed using certain elements that, when combined with oxygen, form a new material that exhibits semiconductive behavior. For example, the semiconductive behaving material can be “turned off” and can have a low or practically no off-state leakage current, and can be “turned on” and become highly conductive when voltage is applied. Example materials to create an n-type channel for example include, but are not limited to, In₂O₃, SnO₂, In GaZnO, and ZnO. Example materials that can be used to create a p-type channel may be formed utilizing, for example, SnO. These materials may be further doped to improve the electrical characteristics. These materials may also be referred to as conductive oxides or semiconductive behaving oxides for the purposes of this discussion.

As 2D materials can have a very large mobility, the 2D materials can be herein described as one embodiment, however it is to be appreciated that other non-epitaxially grown materials can be utilized. Since a 2D material can be precisely deposited on an insulative sheet, this can enable a very low Dt integration build of horizontal nanosheets with high performance. Advantageously, any base substrate material can be utilized as no epitaxial growth is required and the base substrate can be removed for further stacking of the devices.

Carrier nanosheets can be used to provide support for the 2D material layers. Carrier nanosheets can include dielectric materials or semiconductor materials on which 2D material layer, such as a monolayer of 2D material, can be deposited, grown or otherwise formed. Carrier nanosheets can include an electrically insulating material that can be used as a seed layer for the 2D material(s) used in the stack. Additionally or alternatively, a seed layer can include a material that can be deposited onto a carrier nanosheet, onto which a layer of 2D material can be formed, deposited, or otherwise applied.

Reference will now be made to the Figures, which for the convenience of visualizing the 3D semiconductor fabrication techniques described herein, illustrate a substrate undergoing a process flow in both top and cross-sectional views. Unless expressly indicated otherwise, each Figure represents one (or a set) of fabrication steps in a process flow for manufacturing the devices described herein. In the top and cross-sectional views of the Figures, connections between conductive layers or materials may be shown. However, it should be understood that these connections between various layers and masks are merely illustrative, and are intended to show a capability for providing such connections, and the connections should not be considered limiting to the scope of the claims. Conversely, when example illustrations do not show electrical connections to components that are electrically contacted, it is understood that such electrical connections can be made as understood by a person of ordinary skill.

Although the Figures and aspects of the disclosure may show or describe devices herein as having a particular shape, it should be understood that such shapes, whether of the structures or features, are used as examples of the present solution and are merely illustrative and should not be considered limiting to the scope of the techniques described herein. For example, although most of the Figures show various layers in a rectangular shaped configuration, other shapes are also contemplated, and indeed the techniques described herein may be implemented in any shape or geometry. In addition, examples in which two transistors or devices are shown stacked on top of one another are shown for illustrative purposes only, and for the purposes of simplicity. Indeed, the techniques described herein may provide for one to any number N stacked devices. Likewise, the techniques described herein may provide for one to any number N nanosheets and 2D material channels stacked in a transistor or another device. Further, although the devices fabricated using these techniques are shown as transistors, it should be understood that any type of electric electronic device may be manufactured using such techniques, including but not limited to transistors, variable resistors, resistors, capacitors, memory components, logic gates and components and any other components known or used in the art.

Despite the fact that illustrated embodiments for simplicity and brevity show examples of only a single or double transistor structures being formed using the techniques of the present solution, any number of transistors can be formed above and beside the transistor structures illustrated in examples illustrated, such as may be desired for forming a 3D array of devices.

The structures and methods described herein can utilize a nanosheet based design to fabricate transistors that use 2D material layers as transistor channels along with epitaxially doped regions or metals that can be formed or grown for the transistor source/drain contacts. It is understood that alternatively or additionally, metal contacts or epitaxially doped regions for source and drain contacts can be used, depending on the implementation. Likewise, deposition fill and CMP techniques can be used for fabricating source/drain contacts.

The structures and methods described herein can further use a seed layer which can be formed or grown on a silicon nanosheet to allow for a selective 2D material deposition on top of the seed layer that sits on the silicon nanosheet. Recessing silicon at the junction of source/drain can be used to reduce the current leakage through the silicon nanosheet, thus making the 2D material acting as the only path (i.e., channel) between the source and the drain, minimizing leakage currents. Oxidizing silicon at the junction of source and drain can also be used to reduce the current leakage through the silicon nanosheet, thereby also making 2D material acting as the only path (i.e., channel) between the source and drain. It is understood that the same or similar steps can be performed with any number of other materials, including any semiconductor materials known or used.

The structures and methods described herein can further utilize plasma doped silicon nanosheets and/or epitaxially grown doped silicon nanosheets, to reduce leakage current at the channel of the transistor structure. Using these techniques, one or more diode structures can be formed at both ends of the source/drain contacts and doped silicon nanosheet. The diode structure(s) can be formed in an inverse bias with respect to the silicon nanosheet, thereby making the diode structure(s) highly resistive to leakage currents from the source and drain contacts. This resistance to leakage currents can in turn help ensure that the 2D material is the only path (i.e., the channel) between the source and drain.

Described in the Figures below is one or more structures along with one or more methods of fabricating 3D transistor structures that utilize one or more 2D material channels on carrier nanosheets. The following Figures present the solution in which 3D transistors can utilize 2D material channels that can be formed using any number of techniques, such as mechanical exfoliation (ME), chemical vapor deposition (CVD), atomic layer deposition (ALD), and/or sputtering.

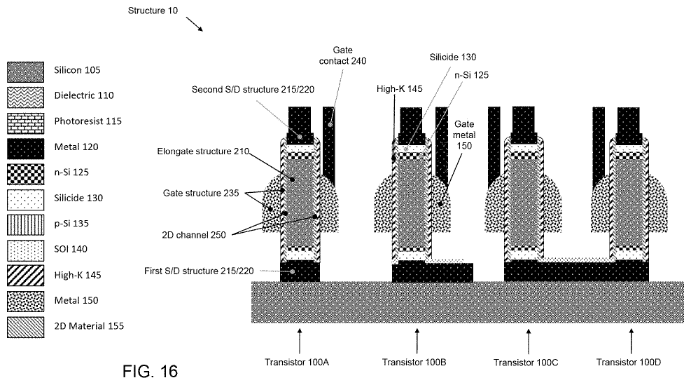

Prior to discussing the fabrication steps for manufacturing the structure 10 of the present solution, it may be useful to first briefly overview the structure 10 and its components. An example structure 10 is illustrated in FIG. 16, in which a cross-sectional view of the structure 10 shows transistor 100A, transistor 100B, transistor 100C and transistor 100D. In this implementation structure 10, all four transistors 100A-D are arrayed beside one another. While the transistors 100A-D are buried in the dielectric 110 material (as will be made apparent in the upcoming Figures and discussions) FIG. 16 for clarity shows these transistors exposed and without the surrounding dielectric 110. As will be visible in further examples, structure 10 can include any number of transistors 100A-N, and in some implementations, transistors 100 can be arranged in a single row or level, such as these illustrated in FIG. 16, while in others transistors 100A-N can be stacked vertically, one above another, in any number of rows.

At a brief overview each transistor 100A-D includes a vertically oriented elongate structure 210 around which 2D channel 250 is formed. 2D channel 250 can include 2D material 155 that can be formed on elongate structure 210. At the base of, below, or at the lower end of the elongate structure 210 is a first source/drain (“S/D”) structure 215/220. At the top, above, or at the upper end of the elongate structure 210 is a second S/D structure 215/220. Laterally surrounding and in contact with the elongate structure 210 is a gate structure 235 that includes high-k 145 material. The high-k 145 material may itself surround or wrap around (to form a ring) the elongate structure 210 and gate metal 150 can also form a ring around the high-k 145 material ring, thereby forming a gate structure 235 that is a gate all around structure. The ring may include encircling one material by another material. The ring may be a full encircling of the material by another material. Alternative configurations are contemplated. Towards the lower end of the elongate structure 210 may be a cross-sectional layer of doped semiconductor material, n-Si 125, below which is a layer of silicide 130 to interface with the first S/D structure 215. Towards the upper end of the elongate structure 210 may be a cross-sectional layer of doped semiconductor material, n-Si 125, above which may be a layer of silicide 130 to interface with the second S/D structure 220. Contacting the gate structure 235 may be a gate contact 240 pointing upwards.

Depending on the implementation, transistors 100A-D can be independently operated or can have some of their components electrically shorted to each other. For example, transistors 100A and 100B have their S/D structures 215/220 and gate structure 235 independent from each other, whereas transistors 100C and 100D have their first S/D structures 215 (e.g., at the lower end) electrically shorted. Metal lines beneath the elongate structures 210 of the transistors 100A-D can be generally referred to as the first S/D structure or contact 215, while the metal lines above the elongate structures 210 can be generally referred to as the second S/D structure or contact 220, although it is understood that source or drain contacts of the transistors 100 can be either S/D structures 215 or 220.

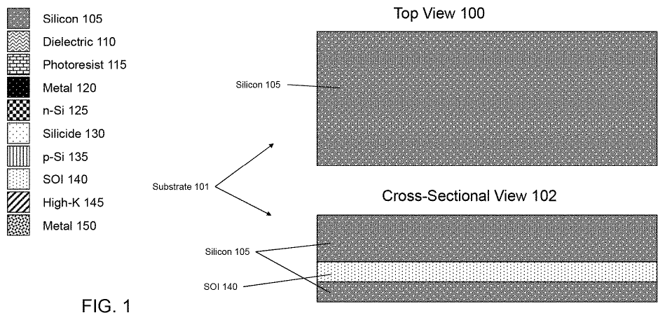

Shown, for example, in FIGS. 1-16, is an embodiment of a fabrication flow for manufacturing a single layer of 3D VFET structures with a 2D material-based channel using a metal-first approach. This fabrication flow can utilize a wafer transfer via oxide-to-oxide bonding, intrinsic silicon, implant-based junction transistor, and a metal first layer design for fabricating transistors with silicon nanosheets and a 2D material channel for parallel channel nanosheet transistor.

In FIG. 1, a top view 100 and a cross-sectional view 102 are illustrated in which a silicon substrate 101 is provided. The silicon substrate 101 can be a silicon on insulator wafer for semiconductor device manufacturing. As seen in cross-sectional view 102, the cross-section of the substrate 101 can include a first silicon 105 layer at the bottom, on top of which can be a layer of silicon on insulator (SOI) 140 material, which can be an oxide or a dielectric material acting as an electrical insulator. On top of the SOI 140 layer can be a second layer of silicon 105, the top surface of which can be used for semiconductor device fabrication steps.

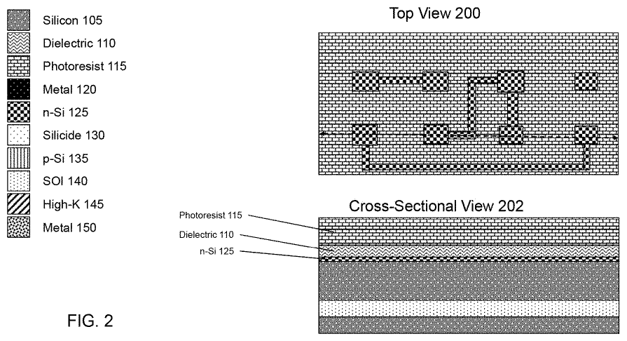

In FIG. 2, a top view 200 and a cross-sectional view 202 are illustrated in which the top surface of the substrate 101 is implanted by n-Si 125, which can be an n-type doped silicon material. Dielectric 110 can be deposited on top of the n-Si 125. Dielectric 110 can include an electrically insulating oxide material. Once dielectric 110 is deposited, it can be patterned using a metal layer mask. The patterning can be done using a layer of photoresist 115 that can be placed on top of dielectric 110. The photoresist 115 can be patterned using lithography and masking or any other means used in the industry. Through patterning of the photoresist 115, patterned shapes for metal layer can be etched downward into the dielectric 110. The etch can be stopped at the surface of the silicon 105 of the substrate 101. The top view 200 can show a patterned etch into the dielectric 110.

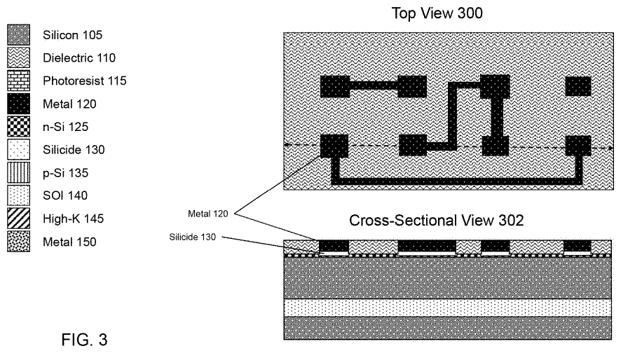

In FIG. 3, a top view 300 and a cross-sectional view 302 are illustrated in which after stripping photoresist 115 from the substrate 101 deposit fill with metal 120 can be performed into the metal patterned etched features implemented in FIG. 2. After completion of the metal fill metal 120, a chemical and mechanical polishing (“CMP”) can be performed to remove any surplus material from the structure. Once a CMP is completed, an annealing step can be performed to form a silicide 130 layer at the interface of the n-Si 125 and metal 120. Silicide 130 layer can reduce the contact resistance of the metal 120 wiring to transistors 100A-N to be completed in transistor structure 100.

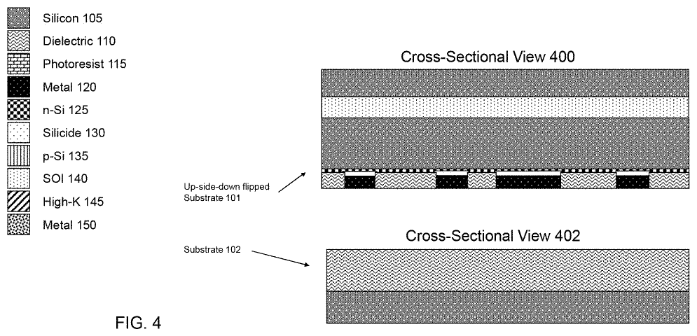

In FIG. 4, a cross-sectional view 400 of the substrate 101 from FIG. 3 above and a cross-sectional view 402 of a new substrate 102 are illustrated. In FIG. 4, substrate 102 is provided with a layer of dielectric 110 at the top surface that is to be bonded with the dielectric 110 surface of the substrate 101. The dielectric 110 (e.g., the oxide) layer of the new substrate 102 can then be bonded with the surface of the substrate 101 that has dielectric 110 with the metal 120 and silicide 130 features formed therein. Substrates 101 and 102 can be bonded so as to form an oxide-to-oxide bond between their two dielectric 110 layers. This can be accomplished, for example, using a thermal annealing process at the temperature range suitable for bonding of the material 110.

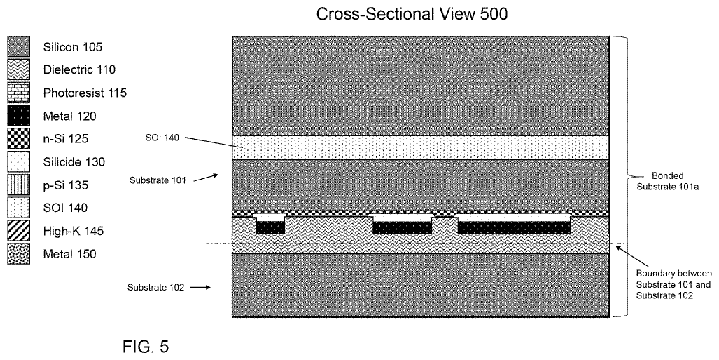

In FIG. 5, a cross-sectional view 500 of the oxide-to-oxide bonded substrates 101 and 102 is illustrated. As a result, the patterned wafer is now flipped. The next step is to detach the back end of the substrate 101 along the layer of the SOI 140, which can be accomplished by selectively etching the SOI 140 material, allowing for the release of the portion of the substrate 101 behind the SOI 140 material layer. By splitting the wafer along the SOI 140 layer, a new surface for fabrication of transistors can be made available for the process to use. The dashed horizontal line across the cross-sectional view 500 shows the delineation between the material from substrate 101 and the material from substrate 102 in the combined bonded substrate 101A.

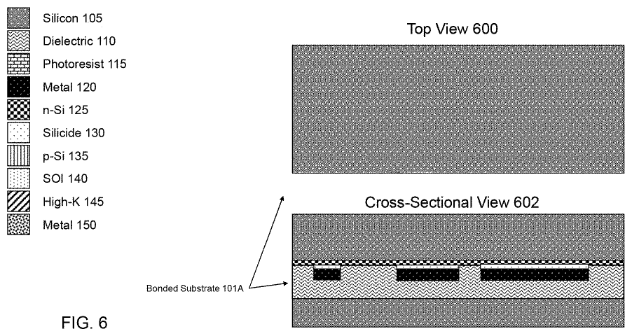

In FIG. 6, a top view 600 and a cross-sectional view 602 are illustrated in which the layer of SOI 140 from substrate 101 has been removed via etching and so the illustration does not show SOI 140 and the portion of the substrate 101 behind the SOI 140. Instead, the bonded substrate 101A can now be flipped around so that the prior SOI 140 surface is the new surface for fabricating the remainder of the structure 10. Due to the bonding, the resulting structure now, which can now be referred to as the bonded substrate 101A, includes the flipped pattern of metal 120 and silicide 130 that are buried the material of the bonded wafers.

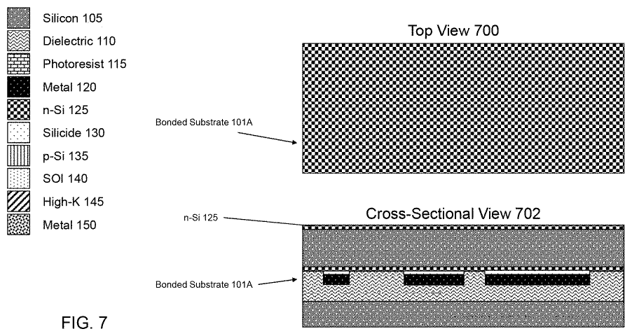

In FIG. 7, a top view 700 and a cross-sectional view 702 are illustrated in which the top intrinsic Si surface of the bonded substrate 101A has an n-type or p-type implant. In the illustrated embodiment, the implant is an n-type implant and marked in FIG. 7 as a layer of n-Si 125, which is an n-type doped region of silicon 105. The cross-sectional view 702 shows the implant layer at the upper end of the bonded substrate 101A.

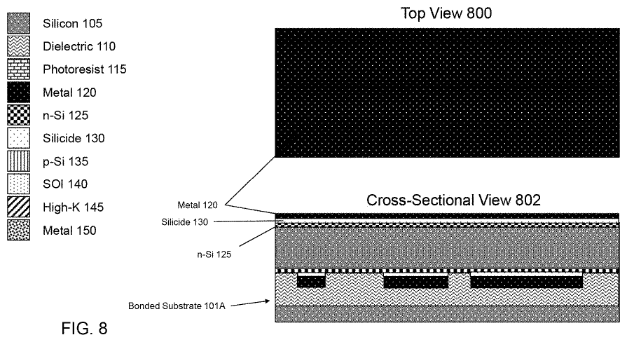

In FIG. 8, a top view 800 and a cross-sectional view 802 are illustrated in metal 120 can be deposited for the source and drain (“S/D”) structures 215/220. As with metal layer in FIG. 3, anneal can be performed to form silicide 130 at the heterojunction of metal 120 and doped silicon 105.

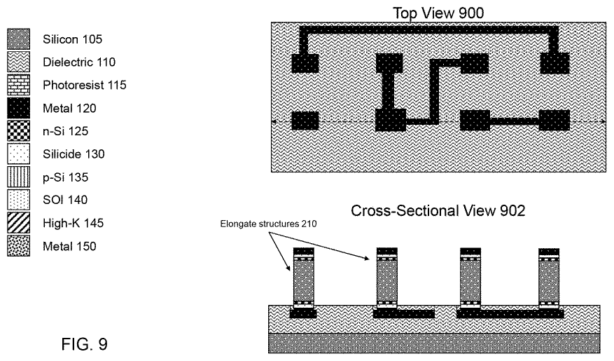

In FIG. 9, a top view 900 and a cross-sectional view 902 are illustrated in which a directional etching can be performed using a nanosheet mask patterning so that metal 120, silicide 130, and silicon 105 are all directionally etched downward to the level of the dielectric 110 oxide layer. In some implementations, the etch can extend into the dielectric 110. The etching can remove the material surrounding the elongate structures 210 formed from the silicon material of the bonded substrate 101A. The elongate structures 210 formed via this etch can include layers of n-Si 125, silicide 130 and metal 120 at the top and the bottom of each elongate structure 210.

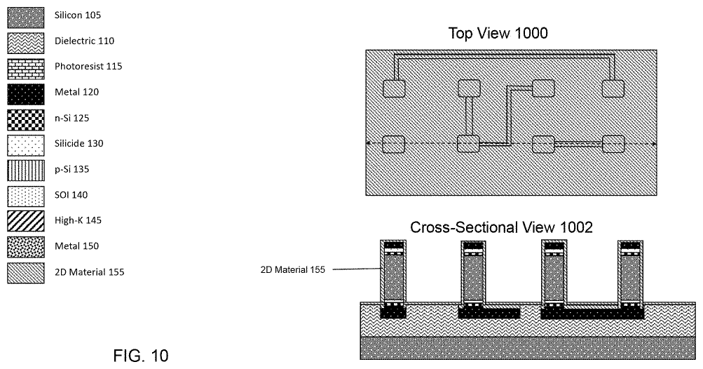

In FIG. 10, a top view 1000 and a cross-sectional view 1002 are illustrated showing the steps in which 2D material 155 is ALD deposited on top of the structures 10 being formed. Deposited 2D material 155 can include a monolayer of 2D material 155 molecules. In some implementations, 2D material 155 can include a thicker material layer with multiple layers of molecules. As 2D material 155 can be electrically conductive, the layer of 2D material 155 covering the structures being formed can provide electrical shorting among various metal 120 lines, and so 2D material 155 will have to be partially etched to prevent electrical shorting from happening.

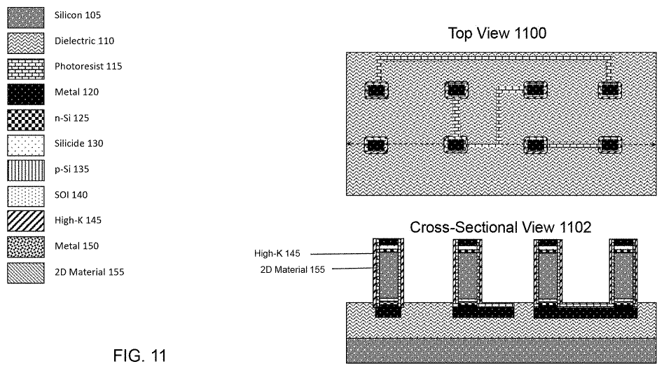

In FIG. 11, a top view 1100 and a cross-sectional view 1102 are illustrated in which high-k 145 can be ALD deposited on top of the 2D material 155. Following the high-k 145 deposition on the 2D material 155, a directional etching of high-k 145, and 2D material 155 can be implemented to remove the interconnections caused by the electrically conductive 2D material between different metal 120 structures of various transistors 100A-D. Once 2D material 155 is removed between metal 120 features (e.g., as seen in the top view 1100) 2D material 155 will no longer short circuit the lines of metal 120. Meanwhile, during this etch process, 2D material 155 deposited on vertically oriented elongate structures 210 can be protected from etchant by high-k 145 and by the vertical geometry of the vertical elongate structures 210.

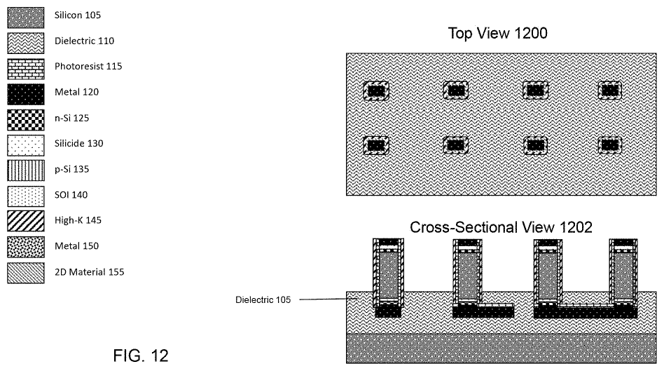

In FIG. 12, a top view 120 and a cross-sectional view 1202 are illustrated in which in which dielectric 110 (e.g., oxide) can be selectively regrown in order to provide electrical insulation and protection of the bottom S/D structures or contacts 215/220.

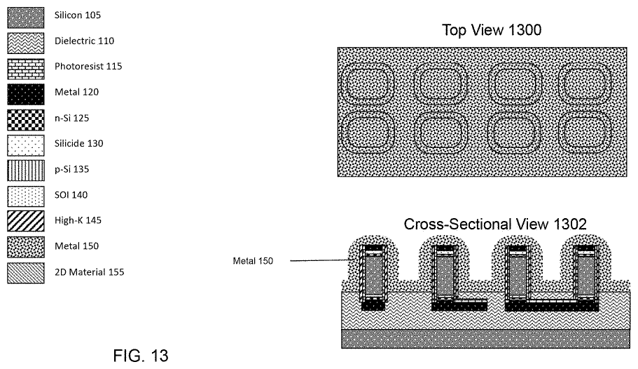

In FIG. 13, a top view 1300 and a cross-sectional view 1302 are illustrated in which gate metal 150 is ALD deposited. As shown in the cross-sectional view 1302, a thick layer of metal 150 can be applied from the top and cover the vertical elongate structures 210 and the areas between the vertical elongate structures 210.

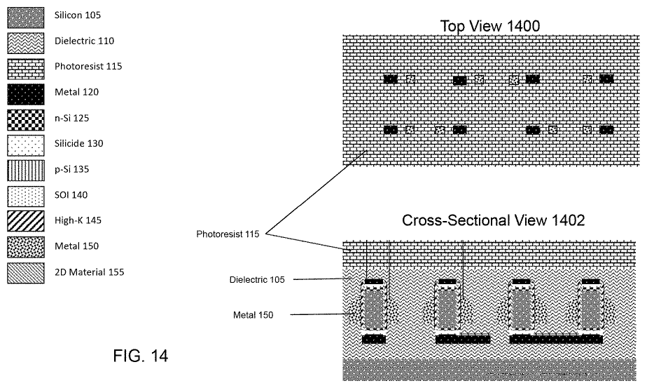

In FIG. 14, a top view 1400 and a cross-sectional view 1402 are illustrated in which metal 155 is directionally etched so as to remove the metal 150 from the top surface in between the elongate structures 210 and lines of metal 120. This directional etching can be performed in a similar fashion as the etching of the high-k 145 and 2D material 155 in connection with FIG. 11.

Once metal 150 is etched so as to remove unintended electrical connections across the elongate structures 210 and metal lines 120, deposit fill with dielectric 110 (e.g., oxide) can be performed to bury elongate structures 210 underneath the dielectric 110. Once dielectric 110 is deposited or grown, a second layer of metal 120 contacts can be patterned using photoresist 115 (not shown). The mask patterning can include the connections for gate structures 235 and for S/D structures 215/220. Dielectric 110 can be etched downward, with the etching being stopped at metal 150.

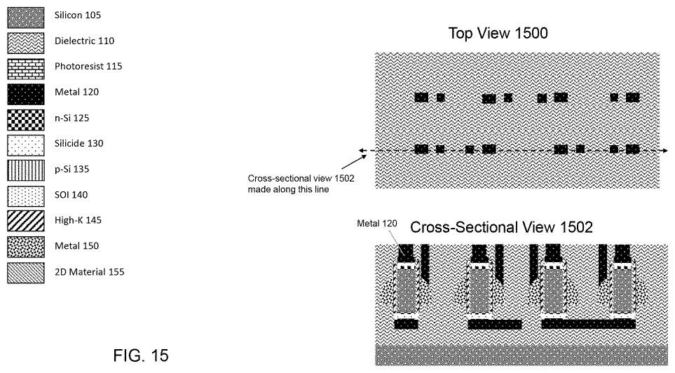

In FIG. 15, a top view 1500 and a cross-sectional view 1502 are illustrated in which after stripping the photoresist 115, a deposit fill by metal 120 layer can be performed, followed by a CMP. It is understood that the routing design for metal 120 deposition can be changed, depending on the design. Similarly, any metal with any work function can be used for this step instead of metal 150 based on the application.

Following the steps in FIGS. 1-15, the structure 10 in FIG. 16 can be completed. As described earlier, resulting transistors 100A-D can each include a first and second S/D structure or contact 215/220 and a gate structure 235. 2D material 155 layers can formed on silicon 105 of the elongate structure 210 and can thereon form 2D channels 250 along the outer surfaces of the elongate structure 210. The gate structure 235 can surround the 2D channel 250 and form a gate-all-around (“GAA”) structure.

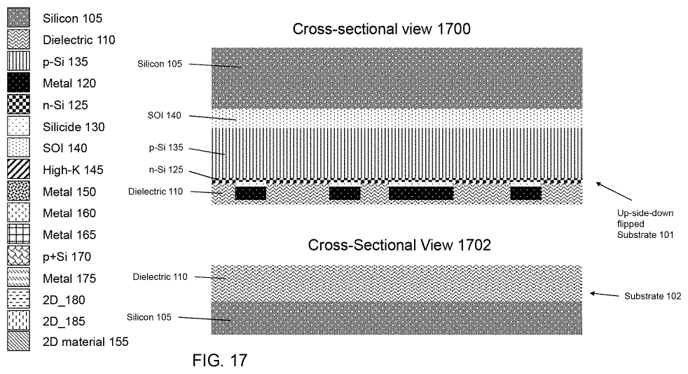

Shown, for example, in FIGS. 17-26, is an embodiment of a fabrication flow for manufacturing N-number of stacks of 3D VFET structures with 2D material based channels. These 3D VFET structures can be fabricated using a wafer transfer technology and a metal first approach. This fabrication flow can provide any number of vertically stacked 3D VFETs in which the polarity of the stack can be varied between the n-type and p-type and different high-k and gate metal and S/D metals can be used as options.

In FIG. 17, a cross-sectional view 1700 and a cross-sectional view 1702 are illustrated showing wafer bonding using oxide-to-oxide techniques discussed in connection with FIG. 4 in which two new example substrates 101 and 102 were bonded to form another example of a bonded substrate 101A. The substrate 101 can be the same or similar type of substrate as the one that is processed in FIGS. 1-4 (e.g., intrinsic or non-doped silicon 105 with SOI 140 layer) or it can be a different substrate, such as a p-type doped or an n-type doped silicon or other semiconductor substrate with SOI 140 layer, or any other oxide or dielectric layer for wafer splitting and flipping to be performed. In the illustrated implementation, the new substrate with which substrate 101 is bonded in FIG. 17 includes a p-type doped Si (e.g., p-Si 135) instead of the intrinsic silicon 105 that was the case with substrate 101 in FIG. 4.

More specifically, in FIG. 17, the substrate used for bonding can include a layer, or a top surface, comprising p-Si 135, which can be a mildly p-doped silicon 105. Similar to the situation in connection with FIG. 4, the substrate can be patterned and processed to include portions of S/D structures 215/220 made with metal 120 as well as doped silicon 105 (e.g., n-Si 125) and silicide 130. The substrate can also include a layer of dielectric 110 (e.g., oxide layers on the surface) in order to perform the oxide-to-oxide bonding, using same or similar fabrication steps as those described in connection with FIGS. 4-5.

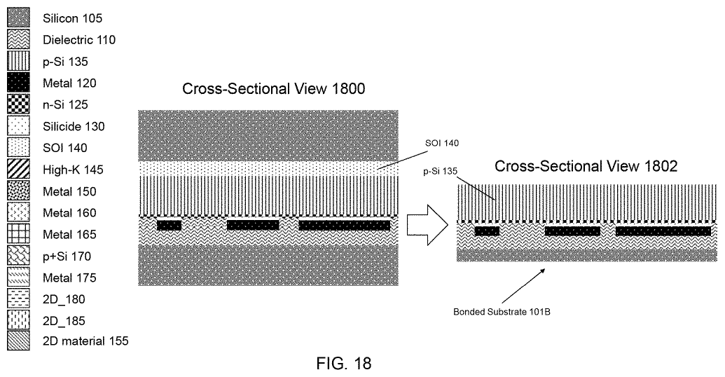

In FIG. 18, a cross-sectional view 1800 and a cross-sectional view 1802 are illustrated in which the same or similar steps are performed as in connection with FIGS. 5-6. SOI 140 layer can be etched out in order to remove the back end of the substrate behind the SOI 140 layer. As shown in FIG. 18, once the SOI 140 layer is etched out and the back of the substrate is removed, the resulting bonded substrate 101B can include the embedded metal 120 and silicide 130 structures along with p-Si 135 layer on its top surface on which the fabrication process can continue to complete the elongate structure 210.

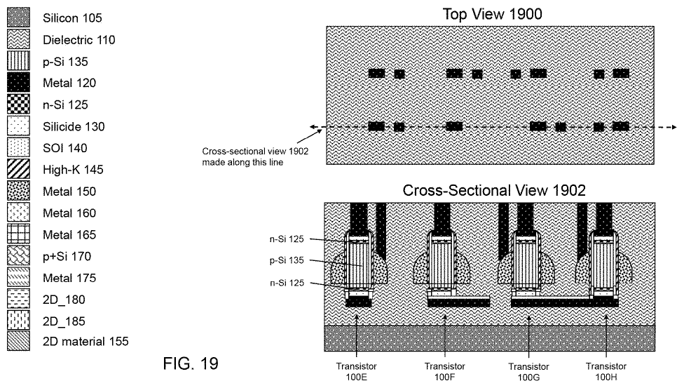

Referring now to FIG. 19, a top view 1900 and a cross-sectional view 1902 are illustrated in which the same or similar steps as those performed in connection with FIG. 15 are to be performed on the structures 10. As such, the structures formed in FIG. 18 can be subjected to the series of fabrication steps and techniques same or similar to those discussed in connection with FIGS. 6-15. A difference between the elongate structures 210 in FIGS. 1-16 and the elongate structures 210 shown in FIG. 19 is that elongate structures 210 in FIG. 19 include a slightly p-doped silicon 105 material—i.e., the p-Si 135, as opposed to intrinsic silicon 105. Moreover, because of the p-doped silicon 105 of the elongate structure 210 in FIG. 19, the n-type doped cross-sectional layers near the top and the bottom of the elongate structure 210 comprising n-Si 125 can help form p-n junctions with the p-Si 135.

More specifically, FIG. 19 also shows transistors 100E, 100F, 100G, and 10011 that can be same or similar as transistors 100A-D in FIG. 16, except that their elongate structures 210 comprise a p-doped silicon 105 (e.g., p-Si 135). This can result in a p-n junction being formed at the interfaces of the n-Si 125 doped cross-sectional layers and the p-type doped silicon 105. Moreover, due to the change in the material forming elongate structure 210, a different 2D material 155 can be used in transistors 100E-H of FIG. 19 than was used in transistors 100A-D.

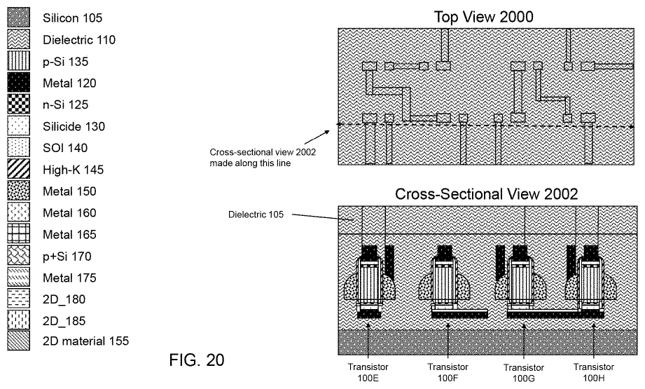

In FIG. 20, a top view 2000 and a cross-sectional view 2002 are illustrated in which dielectric 110 can be deposited and patterned using interconnect routing mask along with a photoresist 115 (not shown). An etch can be performed on dielectric 110 with etch stop on metal, such as metal 120 of the S/D structures 215/220 and gate structures 235 of transistors 100A-D. This layer can allow to connect the S/D structures 215/220 and the gate structures 235 to the outer pad as well as interconnect between each other, as per circuit design requirements and depending on the implementation.

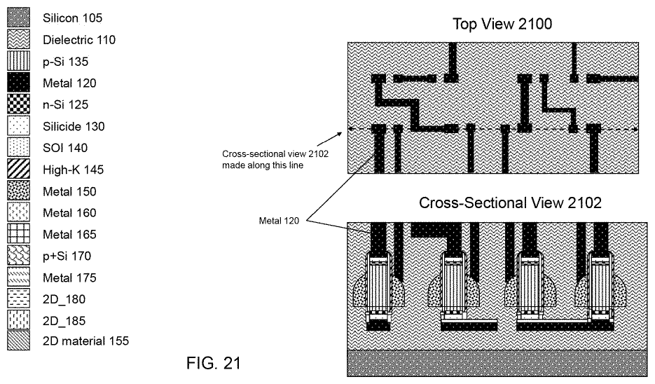

In FIG. 21, a top view 2100 and a cross-sectional view 2102 are illustrated in which photoresist 115 (not shown) can be removed or stripped and a metal 120 filling can be completed into the etched out patterned areas. Following metal 120 filling, a CMP can be performed. While in this step metal 120 can be used, it is understood that any type of metal for producing routing or lines can be used instead.

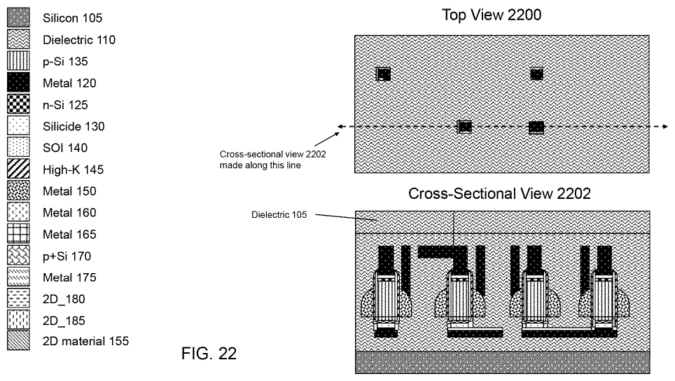

In FIG. 22, a top view 2200 and a cross-sectional view 2202 are illustrated in which dielectric 110 can be deposited and patterned using via mask and a photoresist 115 (not shown). Then, dielectric 110 can be etched using the exposed pattern with an etch stop on the metal (e.g., metal 120 or whatever was used for transistors 100E-H). This can connect the bottom and top transistor layers and maintain hierarchy with the contacts.

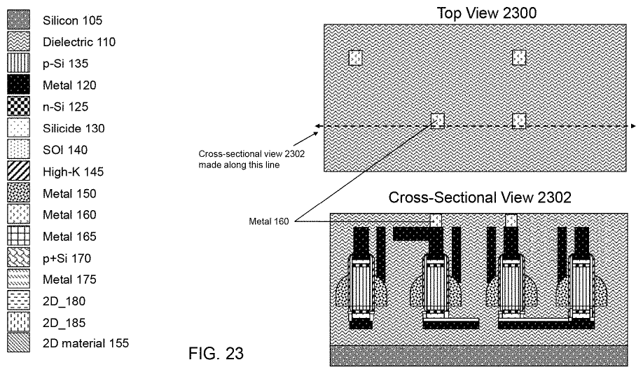

In FIG. 23, a top view 2300 and a cross-sectional view 2302 are illustrated in which photoresist 115 can be stripped. Metal 160 can then be deposited and a CMP can be performed. It is understood that various types of metal line can be used in this step.

The via pads may not be limited to maintain a perfect alignment as the via pads can have a wide scope of area to spread in the layer which can accommodate misalignment due to the wafer transfer of the hierarchical transistor layers. Via top pad size or the bottom metal layer pad size of hierarchical transistor set can be exercised to reduce or remove the misalignment effects.

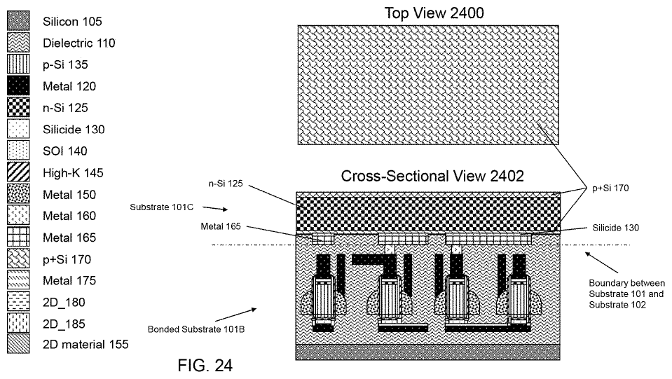

In FIG. 24, a top view 2400 and a cross-sectional view 2402 are illustrated in which another transistor oxide-to-oxide bonding can be performed. Specifically, a bonded substrate 101B can be bonded with a new substrate 101C to enable fabrication of the next layer of transistors 100 that are above the transistor layer comprising transistors 100E-H. As the new transistors to be fabricated should include an n-type doped silicon 105 material, the new wafer substrate 101C can include a slightly n-type doped material (e.g., n-Si 125) instead of the slightly p-type doped wafer in connection with FIGS. 17-18. The new wafer substrate 101C can also include SOI 140 material or any other similar material that can be etched thereafter to remove the remainder of the substrate and provide a new surface for fabricating the elongate structures 210 of the new layer of transistors 100.

As with the example in FIGS. 17-18 and also the prior example in FIGS. 1-4, before the wafer bonding is to be completed, S/D structure 215/220 metal contacts, implant doping and silicide 130 layer for the new elongate structures 210 can be implemented on the new wafer substrate 101C. The metal features can be performed using metal 165, and a p+Si 170 dopant layer can be implanted on top of the slightly n-type doped silicon 105. Then, a dielectric 110 layer can be grown around the metal 165 structures to enable the bonding of the substrate 101C with the bonded substrate 101B in which transistors 100H-G are formed.

As with the transfer in FIGS. 17-18, in FIG. 24 oxide-to-oxide bonding can also be performed via dielectric 110, followed by a SOI 140 etch removal and removal of the back or distal end of the substrate. In this step, a different doping concentration than in the prior wafer bonding in connection with FIGS. 17-18 is shown. The Si 105 body of the elongate structures 210 in these transistors 100 can be lightly n-doped and by following the same process steps as in FIGS. 6-15 or FIG. 19, one or more p+-implanted layers can be used for a p-n junction. Likewise, silicide 130 can be formed between the metal and the n-type doped Si 105 by annealing, just as it can be formed between the metal and the p-type doped Si 105. Since different polarity of Si 105 has been demonstrated, different metal (e.g., metal 165) can be used for the S/D structures 215 and 220. However, it is understood that different metal materials can be used for the purpose of forming S/D structures 215 and 220.

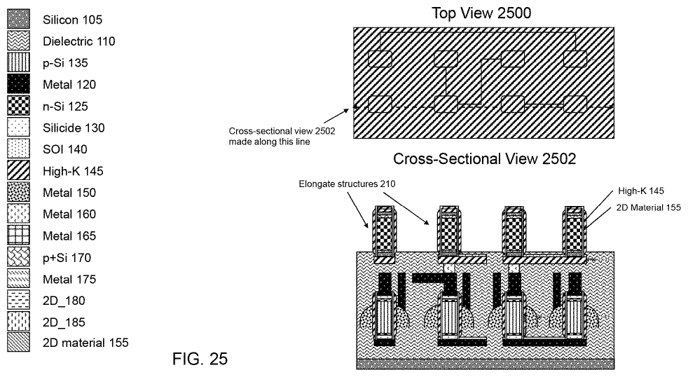

In FIG. 25, a top view 2500 and a cross-sectional view 2502 are illustrated in which the same or similar steps and techniques as described in connection with FIGS. 8-11 can be performed to form elongate structures 210, coat them with 2D material and high-k 145. Following these steps, an etch of any surplus 2D material and high-k 145 forming unintended short circuits across structures or metal lines can be performed. In FIG. 25, instead of 2D material 155, a different 2D material, such as metal 175, can be used to match with the polarity of the doped silicon. It is understood that different types of 2D material can be used for p-type and n-type polarity transistors, depending on their material properties.

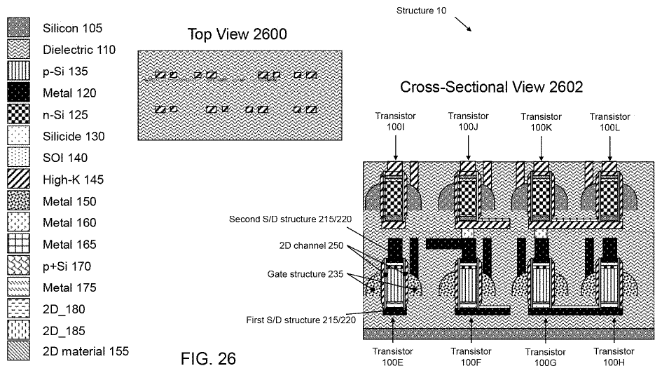

In FIG. 26, a top view 2600 and a cross-sectional view 2602 are illustrated in which the same procedure as explained in FIGS. 13-15 is performed, except that in FIG. 26, the intrinsic silicon 105 material is replaced by a doped silicon 105.

As shown in cross-sectional view 2602 in FIG. 26, the structure 10 can include two levels of transistors 100: a lower level that comprises transistors 100E, 100F, 100G and 10011 and the upper level that comprises transistors 100I, 100J, 100K and 100L. Transistors 100E-H can comprise elongate structures 210 formed predominantly with p-type doped silicon material and having n-type cross-sectional thin layer implants at or near the lower and upper ends of the structures 210, while transistors 100I-L can include elongate structures 210 formed predominantly with n-type doped silicon material and having a p-type cross-sectional thin layer implants at or near the lower and upper ends of the elongate structures 210. Each of the transistors 100 in either levels can include its own S/D structures 215/220, gate structures 235 and one or more 2D channels 250 on the outer surface(s) of the elongate structures 210.

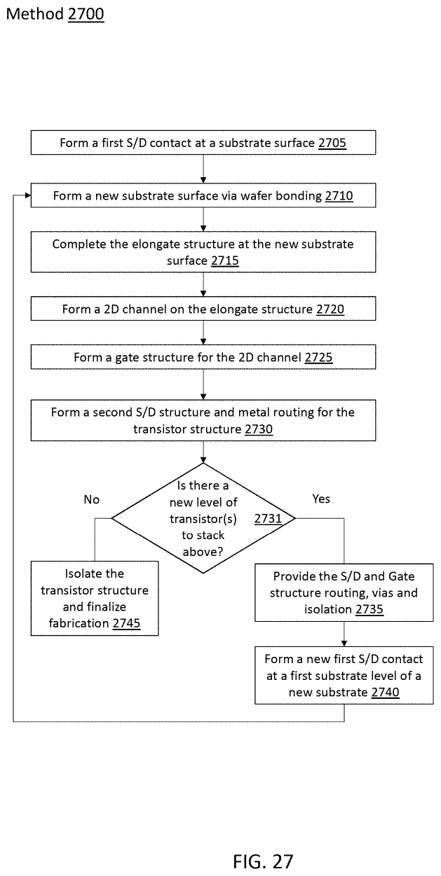

Referring now to FIG. 27, illustrated is a flow diagram of an example method 2700 for fabricating one or more levels of VFET transistors with 2D parallel channels fabricated by wafer bonding or transfer technology and the metal first approach. The method 2700 can include any techniques or fabrication steps discussion in FIGS. 1-26. In some aspects, the method 2700 relates to process steps for fabricating one or more VFET structures with 2D channels 250 using any combination of intrinsic semiconductor wafers, p-type doped semiconductor wafers and n-type doped semiconductor wafers. The semiconductor wafers used can include a layer of SOI 140, or any other material, that can be used to separate a wafer along its thickness. The method 2700 can provide a process for fabricating any number of VFET transistors in a level and any number of levels of transistors 100 one above another.

The method 2700 of FIG. 27 can include a series of steps 2705 to 2745 for fabricating structures described in FIGS. 1-26. Step 2705 can include forming a first S/D contact at a substrate surface. Step 2710 can include forming a new substrate surface using wafer bonding. Step 2715 can include completing the elongate structure via the new substrate surface. Step 2720 can include forming a 2D channel on the elongate structure. Step 2725 can include forming a gate structure for the 2D channel. Step 2730 can include forming a second S/D structure and metal routing for the transistor structure. At step 2731, a determination can be made on whether or not there is another level of transistors to add above the present level of transistors. In the event that at step 2731 affirmative determination is that another level of transistors is to be added above the present level of transistors, then the method 2700 continues at step 2735, which can include providing for S/D and gate structures routing, vias, and isolation. Step 2740 can include forming a new first S/D contact at a first substrate level of a new substrate, after which the process returns to step 2710 for completing the new level of transistors. Alternatively, in the event that at step 2731 negative determination is that another level of transistors is not to be added above the present level of transistors, then step 2745 can include isolating the transistor structure and finalizing the fabrication.

At step 2705 a first S/D contact of a transistor can be formed at a substrate surface. As shown, for example in FIG. 1, a wafer substrate can be provided. Also, as discussed in FIGS. 2-3, a first surface of the substrate can be used to implant dopants into the substrate, including for example an n-type dopant or a p-type dopant and a layer of dielectric or oxide can be grown, deposited, or otherwise formed on top of the doped material. A photoresist can be used to etch a pattern into the dielectric and a metal for forming at least a portion of the first S/D structure of a transistor can be deposited into the patterned material. The first S/D structure can be a source or a drain, depending on the implementation or circuit design.

In some embodiments, a first end of an elongate structure 210 can be formed along with the S/D structure. For example, a layer of material for forming a portion of the elongate structure can be formed on the substrate prior to bonding the wafer substrate wafer with another wafer substrate. A portion of the elongate structure formed can include a layer of dielectric, semiconductor, metal, silicide or other portion of the elongate structure that can be formed.

At step 2710, a new substrate surface for completing transistor fabrication can be formed using one or more wafer bonding techniques. For example, a new substrate surface can be formed by first oxide-to-oxide bonding a new substrate with the substrate that includes the structures formed at step 2705 (e.g., substrate 101) and then cleaving or removing portion of the substrate along a layer of dielectric or oxide running through the thickness of the substrate. The new substrate can include on its top surface a layer of dielectric or oxide that matches the dielectric or oxide present at the surface of the substrate 101 having structures formed at step 2705. The oxide-to-oxide bonding of the two substrates can be implemented using steps or techniques discussed in connection with FIG. 4-5, 17-18, or 24, including an annealing process at a temperature sufficient to form the bond between the two oxide layers.

A new substrate surface for fabricating the remainder of the transistor structures can be formed, for example, by taking the bonded substrate and removing or cleaving a back portion of the bonded substrate. The portion of the wafer substrate to be cleaved or removed can be the portion behind a layer of dielectric, oxide, or other material layer that can be etched out. For example, a substrate can include a layer of oxide material, such as SOI 140, forming a plane across the entire substrate at a set depth. The same substrate can also include a layer of either intrinsic or doped semiconductor (e.g., silicon 105 that is n-type doped or p-type doped). The oxide layer intersecting the substrate (e.g., SOI 140) can be removed by etching, after which the back plane of the substrate that is no longer needed can be removed. The remaining surface of the substrate that was previously interfacing with the etched out material (e.g., SOI 140) can be the new surface on which the fabrication of transistors can continue. Depending on the wafer substrate, the new surface can include an intrinsic silicon material, a p-type doped silicon material, an n-type doped silicon material, or any other doped or intrinsic (e.g., not doped) semiconductor material known or used in the industry for device fabrication.

At step 2715 the fabrication of the elongate structure can be completed via, around, or through the new surface formed at step 2710. Fabrication of the elongate structure can be implemented in accordance with any techniques or steps described in connection with FIG. 7-9, 19, or 25. For example, the portion of the substrate underneath the new surface can be ion implanted and metal deposited. The same portion of the substrate can be annealed to form a silicide layer between the ion implanted region and the metal. The elongate structure can then be patterned and a directional etched to form elongate structures in the material, at, around and/or underneath the new surface. Elongate structures can each be vertically oriented with respect to the plane of the substrate surface. Elongate structures can extend perpendicularly from the plane of the substrate or materials on which the elongate structures are disposed.

Depending on the depth of the etching of the pattern, elongate structures can include any length, including a length of one or more nanometers, tens of nanometers or hundreds of nanometers. Likewise, the width of the elongate structures can be single nanometers, or tens of nanometers. The elongate structures can have their length the same or greater than width. The ratio of length to width can be any ratio, including: 1:1, 1:1.5, 1:2, 1:3, 1:4, 1:5, or 1:10, with the larger numbers denoting the length of the structure with respect to its width size. The elongate structures can include a round, elliptical, square, rectangular, triangular, polygonal, finned, star shaped or any other shaped cross-section.

At step 2720, one or more 2D channels can be formed on the elongate structure. 2D channels can be formed with 2D materials, such as the 2D material 155. One or more 2D channels can be formed on the outer surface walls of the elongate structure, including its side walls that run along the length of the elongate structure. In some embodiments, a different 2D channel can be formed on each individual outer surface of the elongate structure, which depending on configuration can include any number of surfaces. In some embodiments, a 2D channel is formed on only one of a plurality of surfaces of the elongate structure. In some embodiments, a 2D channel is formed one two or more surfaces of the elongate structure. In some embodiments, a single 2D channel is formed on the entire outer surface of the elongate structure. In some embodiments, a 2D channel is formed across all outer surfaces of the elongate structure, except for the top and bottom surfaces.

2D channel can be formed to run across the entire length of the elongate structure. 2D channel can also be formed to cover only a portion of the elongate structure, such as its central portion, top half, bottom half, about three fourths of the length of the elongate structure or any other section or portion of the elongate structure. For example, a layer of seed material can be applied or included on the elongate structure and 2D channel can be formed on the portion of the elongate structure that includes the seed layer.

2D channel can be formed by applying 2D material on the elongate structure. 2D channel can be formed by ALD deposition of 2D material. 2D channel can be formed by chemical vapor deposition, molecular beam epitaxy, electron beam physical vapor deposition or any other type and form of deposition that can be used for any 2D material. 2D channel can be formed by using a seed layer to selectively apply monolayer of 2D material thereon. In some embodiments, elongate structure material (e.g., intrinsic or doped silicon) can act as a seed layer for selective monolayer application of 2D material. In some embodiments, and depending on the 2D material type, any thickness of 2D material can be applied including multiple layers of 2D material. 2D material can also be applied including via epitaxial growth or ion implantation into semiconductor material.

Step 2725 can include forming a gate structure for the 2D channel. A gate structure can include a high-k material and a metal gate material. A gate structure can interface with the 2D channel along only one side of the elongate structure, such as along one of a plurality of surfaces along the length of the elongate structure. Alternatively or additionally, the gate structure can partially or fully be wrapped around, encircle, or otherwise surround the 2D channel. In the embodiments in which a 2D channel is formed along one or more or all outer surfaces of the elongate structure along its length, a gate all around can be formed. A high-k material can cover 2D material, and the metal gate material can cover the high-k material. The high-k material can act as an electrical insulator for the 2D material and the gate metal material.

In some implementations 2D material forms a ring around the length of the elongate structure, a high k layer forms a ring around the 2D material and a gate metal forms a ring around the high-k material. In some embodiments, the elongate structure, 2D material, high-k material and a gate metal each physically interface with each other. In some embodiments, one or more other material layers, such as a dielectric, a seed layer, a semiconductor layer or a metal layer can be interposed between any two of the elongate structure, 2D material, high-k material or gate metal.

A high-k material can be applied so as to blanket cover the 2D material. The high-k material and the 2D material can then be etched from at least the spaces between the S/D structures and its contacts so as to prevent electrical shorting of the S/D structures by the 2D material. This can be implemented for example using steps or techniques discussed in connection with FIGS. 10-11. A layer of dielectric can be grown around the S/D structures formed by the metal lines so as to prevent electrical shorting by the gate metal.

Gate metal can be formed around the high-k material and the 2D material. In some embodiments, a gate metal forms a ring around a high-k material and the high-k material forms a ring around the 2D material that forms a ring around the elongate structure, which can be called a gate all around structure. In some embodiments, gate metal forms a ring around the high-k material which can cover only a subset of surfaces of the elongate structure. In some embodiments, gate metal interfaces with or covers a high-k material that interfaces with and covers only a subset of surfaces of the elongate structures, such as at least one, or two, or three surfaces of an elongate structure having a rectangular or any other polygonal cross-section. Gate structure can be formed using any techniques or steps discussed in connection with FIG. 11-13, 19, or 26.

Step 2730 can include forming a second S/D structure and metal routing for the transistor structure. A second S/D structure 215 or 220 can be formed to contact a top portion of the elongate structure. The second S/D structure can be a source or a drain. The second source/drain contact can be implemented by etching a dielectric and depositing metal and/or including any steps discussed in connection with FIG. 14, 15, or 20. Depending on the implementation the second S/D structure of a transistor can be routed independently from any other S/D structure of another transistor, or the S/D structure can be electrically shorted.

Step 2731 can include a determination of whether or not there is a new level of transistors to fabricate or stack above the present level of transistors. In designs in which multiple layers of transistors are stacked one on top of another, the answer to this question is yes and the process then moves on to steps 2735 and 2740. In the designs in which only a single layer of transistors is to be completed, the process moves on to step 2745.

At step 2735, routing, vias and isolation can be provided for the S/D structures and the gate structures. For example, a series of vias or routing metal lines can be formed to provide electrical power to S/D structures and/or gate structures. One or more dielectric layers can be grown around the formed transistors or their components, including for example their S/D structures, gate structures and any other metal contacts or vias, in order to electrically insulate and provide the protection for the transistors. Metal vias, routing, and contacts can be added to the transistors, along with layers of dielectrics, such as shown in steps provided in FIGS. 20-23.

At step 2740, a new first S/D contact at a first substrate level of a new (wafer) substrate can be formed. For fabricating a new level of transistors, a new wafer substrate can be used to implement the same or similar steps as those discussed in connection with FIGS. 1-3. The new substrate can include the same or similar substrate as the one discussed in step 2705. The new substrate can include an intrinsic semiconductor substrate, a p-type doped substrate or an n-type doped substrate and can further include a layer of material, such as the SOI 140 material, which could later be etched out in order to cleave the substrate and remove its back end. In some embodiments, along with the new first S/D contact a new first end of a new elongate structure can be formed, just as with step 2705.

Once the step 2740 is complete, the process can then return to step 2710. This repeating of the process starting at step 2710 can be made for any additional number of layers of transistors to be completed.

Alternatively, in the event that at step 2731 it is determined that no additional levels of transistors are to be stacked above the current level, at step 2745, the transistor structure can be isolated and the fabrication can be finalized. For example, a layer of dielectric or oxide can be grown around the transistors in order to provide the protection for them, such as performed in connection with FIG. 14-15 or 26. Any metal routing or interconnections between the S/D structures and gate structures can be completed, depending on the design goals, such as whether the transistors are to be used as a part of a memory, a gate logic, a microcontroller, a processor or any other structure known or used in the field. The fabrication can at this point be finalized.

Having now described some illustrative implementations and implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements and features described only in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation, and references to “an implementation,” “some implementations,” “an alternate implementation,” “various implementation,” “one implementation” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The preceding description of the disclosed embodiments is provided to enable any person skilled in the art to make or use the embodiments described herein and variations thereof. Various modifications to these embodiments will be readily apparent to those skilled in the art, and the principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

While various aspects and embodiments have been disclosed, other aspects and embodiments are contemplated. The various aspects and embodiments disclosed are for purposes of illustration and are not intended to be limiting, with the true scope and spirit being indicated by the following claims.

What is claimed is:

1. A device comprising:
an elongate structure extending vertically from a first/source drain contact, a first end of the elongate structure in electrical contact with the first source/drain contact;
a second end of the elongate structure in electrical contact with a second source/drain contact;
a channel including a 2D material layer extending along an external surface of the elongate structure; and
a gate structure including a high-k dielectric extending along the 2D material and a gate metal in contact with the high-k dielectric.

2. The device of claim 1, wherein:
the 2D material layer is in contact with and forms a ring the external surface of the elongate structure;
the high-k dielectric is in contact with and forms a ring around the 2D material layer; and
the gate metal forms a ring around the high-k dielectric.

3. The device of claim 1, wherein the first source/drain contact is formed in a material of a first substrate and the elongate structure is formed in a material of a second substrate.

4. The device of claim 1, further comprising a silicide layer disposed between the elongate structure and the first source/drain contact.

5. The device of claim 1, further comprising a layer of dielectric material disposed between the gate structure and the first source/drain contact.

6. The device of claim 1, wherein the elongate structure comprises a doped semiconductor material.

7. The device of claim 6, further comprising a second doped semiconductor material of the elongate structure comprising a first polarity and the doped semiconductor material comprising a second polarity, the doped semiconductor material and the second doped semiconductor material forming a p-n junction.

8. The device of claim 1, further comprising:
a second elongate structure extending vertically from a third source/drain contact, a first end of the second elongate structure in electrical contact with the third source/drain contact;
a second end of the second elongate structure in electrical contact with a second source/drain contact;
a second channel including a 2D material layer extending along an external surface of the elongate structure; and
a second gate structure including a high-k dielectric extending along the 2D material; and
a gate metal in contact with the high-k dielectric, wherein the second elongate structure is formed above the elongate structure.

9. The device of claim 8, further comprising the third source/drain contact formed above the first source/drain contact and the second source/drain contact.

10. The device of claim 8, further comprising
a portion of the elongate structure comprising a semiconductor material doped with a first polarity and a cross-sectional slice of semiconductor material doped with a second polarity; and
a portion of the second support structure comprising a semiconductor material doped with the second polarity and a cross-sectional slice of semiconductor material doped with the first polarity.

11. A method comprising:
forming an elongate structure extending vertically from a first/source drain contact, a first end of the elongate structure in electrical contact with the first source/drain contact;
forming a second end of the elongate structure in electrical contact with a second source/drain contact; and
forming a channel including a 2D material layer extending along an external surface of the elongate structure; and
forming a gate structure including a high-k dielectric extending along the 2D material and a gate metal in contact with the high-k dielectric.

12. The method of claim 11, further comprising:
forming a ring of the 2D material layer in contact with and around the external surface of the elongate structure;
forming a ring of high-k dielectric in contact with and around the 2D material layer; and
forming a ring of the gate metal in contact with and around the high-k dielectric.

13. The method of claim 1, further comprising:
forming first source/drain contact in a material of a first substrate, and
forming the elongate structure in a material of a second substrate.

14. The method of claim 11, further comprising forming a silicide layer between the elongate structure and the first source/drain contact.

15. The method of claim 11, further comprising forming a layer of dielectric material between the gate structure and the first source/drain contact.

16. The method of claim 11, further comprising forming the elongate structure including a doped semiconductor material.

17. The method of claim 16, further comprising:
forming a second doped semiconductor material of the elongate structure comprising a first polarity, and
forming the doped semiconductor material comprising a second polarity, the doped semiconductor material and the second doped semiconductor material forming a p-n junction.

18. The method of claim 11, further comprising:
forming a second elongate structure extending vertically from a third source/drain contact, a first end of the second elongate structure in electrical contact with the third source/drain contact;
forming a second end of the second elongate structure in electrical contact with a second source/drain contact;
forming a second channel including a 2D material layer extending along an external surface of the elongate structure; and
forming a second gate structure including a high-k dielectric extending along the 2D material and a gate metal in contact with the high-k dielectric, wherein the second elongate structure is formed above the elongate structure.

19. The method of claim 18, further comprising the third source/drain contact formed above the first source/drain contact and the second source/drain contact.

20. The method of claim 18, further comprising:
forming a portion of the elongate structure comprising a semiconductor material doped with a first polarity and a cross-sectional slice of semiconductor material doped with a second polarity; and
forming a portion of the second support structure comprising a semiconductor material doped with the second polarity and a cross-sectional slice of semiconductor material doped with the first polarity.
